(19) United States
(12) Patent Application Publication
(10) Pub. No.: US 2024/0392438 A1
(43) Pub. Date: Nov. 28, 2024

(54) SUBSTRATE TREATING APPARATUS AND METHOD

(71) Applicant: Jiangsu Leadmicro Nano-Technology Co., Ltd., Wuxi (CN)

(72) Inventors: Xinyuan WU, Wuxi (CN); Baochen LIAO, Wuxi (CN); Xiang LI, Singapore (SG); Weiming LI, Espoo (FI); Peng ZHANG, Wuxi (CN); Yunsong WANG, Wuxi (CN)

(73) Assignee: Jiangsu Leadmicro Nano-Technology Co., Ltd., Wuxi, JS (CN)

(21) Appl. No.: 18/695,828

(22) PCT Filed: May 17, 2023
(86) PCT No.: PCT/CN2023/094772

§ 371 Date: Mar. 27, 2024

(30) Foreign Application Priority Data
May 19, 2022 (CN) 202210547272.8

(51) Int. Cl. C23C 16/455; C23C 16/34; C23C 16/40; C23C 16/44; C23C 16/448; C23C 16/46; C23C 16/50; H01L 21/02

(52) U.S. Cl. CPC C23C 16/45544; C23C 16/345; C23C 16/403; C23C 16/4408; C23C 16/4481; C23C 16/46; C23C 16/50; H01L 21/0217; H01L 21/02178; H01L 21/02274; H01L 21/0228

(57) ABSTRACT

Provided is substrate treating apparatus and method. Apparatus has thermal ALD processing unit and PECVD processing unit integrated. Thermal ALD processing unit comprises carrier gas source, first pipelines, second pipelines, source bottle, oxidation source, first fluid valves, second fluid valves and apparatus cavity; apparatus cavity accommodates substrate, serves as reaction place for substrate; first pipelines and second pipelines are transmitting carrier gas to cavity; carrier gas source provides carrier gas: oxidation source provides oxidizing agent; source bottle accommodates chemical source; when introduced into source bottle, carrier gas carries chemical source into apparatus; first fluid valves controls chemical source to flow or not through first pipelines; second fluid valves controls oxidizing agent to flow or not through second pipelines. Apparatus carries out hot atomic layer deposition on substrate on tubular PECVD apparatus platform, combines aluminum oxide deposition process and silicon nitride deposition process into one apparatus.

### CROSS-REFERENCES TO RELATED APPLICATION

The present application claims the priority of Chinese Patent Application No. 2022105472728 filed on May 19, 2022. The contents of the above application are incorporated herein by reference.

### FIELD OF THE APPLICATION

The present application relates to the technical field of semiconductor processes, and in particular to a substrate treating apparatus and a method thereof.

### BACKGROUND

An existing tubular plasma enhanced chemical vapor deposition (PECVD) apparatus utilizes an ion enhanced technology to carry out deposition of various film layers of a tunnel oxide passivated contact (TOPCon) cell, as shown in FIG. 1, comprising a frontside laminate of aluminum oxide and silicon nitride and a backside laminate of silicon oxide, polysilicon and silicon nitride. Wherein the aluminum oxide plays a vital role in passivating a frontside boron diffusion emitter. For an aluminum oxide process of industrial mass production, an existing process for tubular equipment is mainly based on an ion enhanced process, however, a PECVD technology can not guarantee shape-retention of a thin film on front texturing morphology, and aluminum oxide deposition has a problem of nonuniformity. Meanwhile, a plasma technology may also bring a plurality of bombardment damages to a passivated surface, causing it impossible to achieve a best passivation effect. Therefore, a substrate treating apparatus and a method thereof is required to improve the problems stated above.

### BRIEF SUMMARY OF THE APPLICATION

The present application aims to providing a substrate treating apparatus and a method thereof, performing a thermal atomic layer deposition onto the substrate on a tubular PECVD equipment platform, combining deposition processes of aluminum oxide and silicon nitride into one apparatus.

In a first aspect, the present application provides a substrate treating apparatus, the apparatus integrates a thermal ALD processing unit and a PECVD processing unit; the thermal ALD processing unit comprises: a carrier gas source, a plurality of first pipelines, a plurality of second pipelines, a source bottle, an oxygen source, a plurality of first fluid valves, a plurality of second fluid valves and an apparatus cavity, the apparatus cavity is applied to accommodating a substrate and serving as a reaction place for the substrate; both the first pipelines and the second pipelines are applied to transmitting carrier gas to the apparatus cavity; the carrier gas source is applied to supplying the carrier gas, the oxygen source is applied to supplying an oxidant, the source bottle is applied to accommodating a chemical source; when the carrier gas is introduced into the source bottle, the carrier gas carries the chemical source before entering the apparatus cavity; the first fluid valves are applied to controlling whether the chemical source flows through the first pipelines or not; while the second fluid valves are applied to controlling whether the oxidant flows through the second pipelines or not.

A beneficial effect of the substrate treating apparatus in the present application is that: by transmitting the chemical source and the oxidant uniformly to the apparatus cavity through the plurality of first pipelines and the plurality of second pipelines respectively, a problem of uniformity in depositing the aluminum oxide is solved; the first fluid valves are applied to controlling the source bottle communicate with the first pipelines; the second fluid valves are applied to controlling the oxygen source communicate with the second pipelines. A process condition for performing the thermal atomic layer deposition onto the substrate on the tubular PECVD equipment platform is achieved, while shape-retention of a thin film on texturing morphology of a substrate surface is improved by depositing the thermal atomic layer, and meanwhile, damaging a passivated surface is avoided, thereby being beneficial for achieving a best passivation effect.

In addition, by arranging the pipelines, during a whole ALD process period, gas introduced into the cavity is injected into a vacuum environment through a door end of the cavity before flowing out through an opposite end, wherein a downstream of a gas outflow end has a pump with an inner part entering the cavity arranged, having a gas flow stable, thus making a flow field of the process gas a stable laminar flow, and the process controllable, therefore being able to improve quality of the film layer, further improving quality of a product.

Preferably, the first processing unit is a thermal ALD processing unit, and at least one path of gas in the thermal ALD processing unit is introduced into the apparatus cavity in a pulse mode; and the second processing unit is a PECVD processing unit, and gas in the PECVD processing unit is introduced into a same apparatus cavity in a non-pulse mode.

Preferably, the PECVD processing unit and the thermal ALD processing unit share the carrier gas source and the apparatus cavity.

Preferably, a vacuum process portion of the tubular equipment is a quartz tube with a hot wall, wherein a heater is a combination of heating wires or heating plates having no less than four temperature setting intervals, applied to controlling temperature of the hot wall.

Preferably, the PECVD processing unit and the thermal ALD processing unit share the carrier gas source, the source bottle, and the apparatus cavity.

Preferably, the oxygen source is a gaseous oxygen source or an active plasma oxide.

Preferably, the plurality of reaction pipelines supply independently gas required by the process to the cavity.

Preferably, the carrier gas source has a conversion valve arranged, and the conversion valve is applied to selecting to supply the carrier gas in a same flow to the first pipelines or the second pipelines.

Preferably, the gaseous oxygen source is communicated to the second pipelines through a third pipeline, and the third pipeline has a flow meter arranged inside, while the flow meter is applied to detecting a flow of the gas in the third pipeline; and the second pipelines have an exhaust pipeline arranged at a place close to the carrier gas source, the exhaust pipeline comprises a flow controller, the flow controller controls the exhaust pipeline to exhaust gas through the second pipelines, and a flow of the gas being exhausted is as same as the flow detected by the flow meter.

Preferably, the oxygen source comprises at least two oxidants of different compositions, communicating with the second pipelines respectively.

Preferably, the oxygen source is selectively connected with one of the at least two oxidants of different compositions.

Preferably, at least one oxygen source is an ozone generator, and at least one oxygen source is an oxygen source bottle.

Preferably, the ozone generator has a third pipeline connected, the third pipeline is communicated with the second pipelines, the third pipeline has a flow meter arranged inside, and the flow meter is applied to detecting a flow of the gas in the third pipeline; and the second pipelines have an exhaust pipeline arranged at a place close to the carrier gas source, the exhaust pipeline comprises a flow controller, the flow controller controls the exhaust pipeline to exhaust gas through the second pipelines, and a flow of the gas being exhausted is as same as the flow detected by the flow meter.

Preferably, the source bottle and the first pipelines are arranged in parallel; while the carrier gas flows through at least one of the source bottle and the first pipelines.

Preferably, the source bottle has an adjustment portion arranged for adjusting a flow of the gas entering the source bottle; when the carrier gas flows simultaneously through the source bottle and the first pipelines, the adjustment portion is applied to adjusting a ratio of a flow of the gas distributed to the source bottle.

Preferably, the carrier gas source has a conversion valve arranged, and the conversion valve is applied to selecting to supply the carrier gas in a same flow to the first pipelines or the second pipelines.

Preferably, the apparatus cavity has a furnace mouth flange arranged; both the first pipelines and the second pipelines are connected with the furnace mouth flange; and the furnace mouth flange has a plurality of gas channels arranged, the gas is injected into the cavity along the gas channel, and perpendicularly to a furnace tube, and each gas channel is applied to communicating the apparatus cavity with the first pipelines or the second pipelines respectively.

Preferably, the apparatus further comprises an ozone destructor; the ozone destructor is applied to processing any excess ozone generated by the ozone generator; the ozone generator has the third pipeline and a fourth pipeline connected; while the third pipeline is connected with the second fluid valves, and the fourth pipeline is connected with the ozone destructor.

Preferably, each pipeline is subjected to an anti-oxidation treatment.

Preferably, the anti-oxidation treatment comprises coating with aluminum oxide.

Preferably, the ozone generator is connected with an oxygen source and a nitrogen source; the nitrogen source is applied to controlling a concentration of the ozone generated by the ozone generator; and a concentration of the ozone is set as [16, 20] wt %.

Preferably, the apparatus further comprises a vacuum pump; and the vacuum pump is applied to pumping out gas in a reaction cavity.

Preferably, the apparatus further comprises an exhaust gas treator; and the exhaust gas treator is applied to processing gas pumped out from the reaction cavity, and is also applied to processing gas exhausted from the ozone destructor.

Preferably, the apparatus cavity comprises a heater, the heater is applied to controlling a reaction temperature of the apparatus cavity.

Preferably, the apparatus cavity further has an auxiliary heat tube arranged, the auxiliary heat tube is applied to heating, so as to enable a fast temperature rise of the apparatus cavity.

Preferably, the PECVD processing unit and the thermal ALD processing unit share the carrier gas source and the source bottle.

Preferably, the reaction cavity has a plurality of graphite boats arranged inside; a number of the graphite boats is N, while N is a positive integer; the graphite boat is applied to loading the substrate; and a number of the substrate loaded in the graphite boat is M, while M is a positive integer.

In a second aspect, the present application provides a substrate treatment method, adopting the apparatus in any one of the first aspect, and carrying out thermal ALD and PECVD processing on a substrate in a same cavity; the thermal ALD processing comprises: transmitting the carrier gas to the apparatus cavity through the first pipelines and the second pipelines continuously when the carrier gas source is working; carrying out a first reaction step, comprising: opening the first fluid valves for a t1 period before closing for a t2 period; the carrier gas carrying the chemical source before entering the apparatus cavity through the first pipelines, when the first fluid valves are open; the carrier gas source purging the carrier gas into the apparatus cavity when the first fluid valves are closed; carrying out a second reaction step, comprising: opening the second fluid valves for a t3 period before closing for a t4 period; the ozone generator transmitting ozone to the apparatus cavity through the second pipelines when the second fluid valves are open; the carrier gas source purging the carrier gas to the apparatus cavity when the second fluid valves are closed; and carrying out the first reaction step and the second reaction step alternately for a plurality of times before stopping a reaction.

Preferably, when the substrate enters the apparatus cavity, the heater heats up the substrate; the carrier gas source fills the apparatus cavity with the carrier gas to carry out a pressure maintaining test; while the vacuum pump pumps out gas in the apparatus cavity. The carrier gas source introduces continuously a same flow of the carrier gas into the cavity through the first pipelines or the second pipelines by the conversion valve. The present embodiment is able to ensure that a flow of the gas introduced into the apparatus cavity from the second pipelines is as same as the gas introduced into the apparatus cavity from the first pipelines.

Preferably, the ozone generator is kept in an on state, and excess ozone generated by the ozone generator is treated by the ozone destructor.

Preferably, the ozone generator is kept in an on state, when supplying gas to the second pipelines through the third pipeline, the exhaust pipeline arranged on the second pipeline and close to the carrier gas source exhausts the carrier gas in the second pipelines out, and a flow of the gas exhausted is as same as a flow of the gas in the third pipeline.

Preferably, gas pumped out from the apparatus cavity by the vacuum pump is introduced into the exhaust gas treator; and gas exhausted from the ozone destructor is introduced into the exhaust gas treator.

Preferably, after the substrate completing the thermal ALD process in the apparatus cavity, the substrate continues to perform the PECVD process in the apparatus cavity.

Preferably, the chemical source comprises trimethylaluminum; and a surface of the substrate has a layer of hydroxyl arranged, satisfying a following chemical reaction formula:

nsurf-OH+Al(CH₃)₃→surf-O—Al(CH₃)₃₋ₙ,+nCH₄

wherein, n is 1 or 2.

Preferably, the first reaction step satisfies a following chemical reaction formula:

nsurf-AlOH+Al(CH₃)₃→surf-(nAl)—O—Al(CH₃)₃₋ₙ+nCH₄

wherein, n is 1 or 2; the second reaction step satisfies a following chemical reaction formula:

(3-n)surf-AlCH₃+(3-n)O₃→(3-n)surf-AlCH₂OH+(3-n)O₂

wherein, n is 1 or 2; and a product of the second reaction step satisfies a following chemical reaction formula:

2surf-AlCH₂OH→2surf-AlOH+C₂H₄.

By setting the first reaction step and the second reaction step, the thermal ALD process is realized on the tubular platform for a first time, thus forming a first deposition layer in the apparatus cavity in a pulse mode, such as aluminum oxide, silicon oxide, gallium oxide, titanium oxide or a plurality of other oxides; before further forming a second deposition layer different from the first deposition layer in the same apparatus cavity in a non-pulse mode, such as silicon nitride, in such a way, it is able to avoid a defect in the prior art caused by a direct plasma bombardment onto a surface of a silicon substrate. The present application achieves the thermal ALD process on the tubular platform for a first time, which is relatively simpler comparing to a traditional PEALD process, and it is able to perform a process adjustment by controlling a temperature, introduction flow, introduction time and concentration of the oxygen source and a TMA source only. In addition, by setting of the pipelines, selectivity of different oxygen sources is achieved, while ensuring a flow of a gas entering the cavity unchanged, when the gas is introduced in, thereby ensuring stability of a process.

### BRIEF DESCRIPTION OF THE DRAWINGS

FIG. 1 illustrates a schematic diagram on a deposition structure of various film layers of a TOPCon cell in the prior art;

FIG. 2 illustrates a schematic structural diagram on a substrate treating apparatus according to an embodiment of the present application;

FIG. 3 illustrates a schematic structural diagram on a first apparatus cavity according to an embodiment of the present application;

FIG. 4 illustrates a side view of a second apparatus cavity according to an embodiment of the present application;

FIG. 5 illustrates a schematic structural diagram on another substrate treating apparatus according to an embodiment of the present application;

FIG. 6 illustrates a flow diagram on a substrate treating method according to an embodiment of the present application;

FIG. 7 illustrates a schematic diagram on a region division to the substrate according to the present application;

FIG. 8 illustrates a box diagram on a minority carrier lifetime of a substrate according to an embodiment of the present application;

FIG. 9 illustrates a box diagram on an implied open circuit voltage of a substrate according to an embodiment of the present application;

wherein: 201-apparatus cavity; 202-carrier gas source; 203-ozone generator; 204-source bottle; 205-first pipelines; 206-second pipelines; 207-ozone destructor; 208-vacuum pump; 209-exhaust gas treator; 210-first fluid valves; 211-second fluid valves; 212-oxygen source; 213-nitrogen source; 214-third pipeline; 215-fourth pipeline; 216-heater; 220-gas channel; 221-first gas channel; 222-second gas channel; 230-furnace mouth flange; 240-oxygen source bottle; 301-purging nitrogen source; 302-silane source; 303-electrode.

### DETAILED DESCRIPTION OF EMBODIMENTS

In order to make the purpose, technical solution and advantages of the present application clearer and more explicit, further detailed descriptions of the present application are stated here, referencing to the attached drawings and some embodiments of the present application. Obviously, the described embodiments are part of, but not all of, the embodiments of the present application. Based on the embodiments of the present application, all other embodiments obtained by those of ordinary skills in the art without any creative work are included in the scope of protection of the present application. Unless otherwise defined, technical or scientific terms used herein should have the meanings usually understood by those of ordinary skills in the art to which the present application belongs. As used herein, the terms “comprise” and the like are intended to mean that an element or item appearing before the term encompasses elements or items appearing after the term and the equivalents thereof, instead of excluding other elements or items.

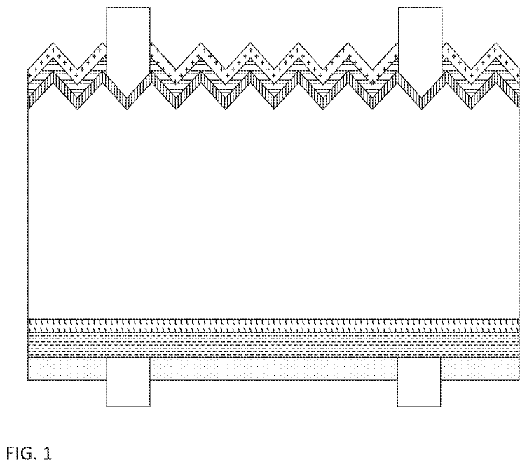

FIG. 1 illustrates a schematic diagram on a deposition structure of various film layers of a TOPCon cell in the prior art.

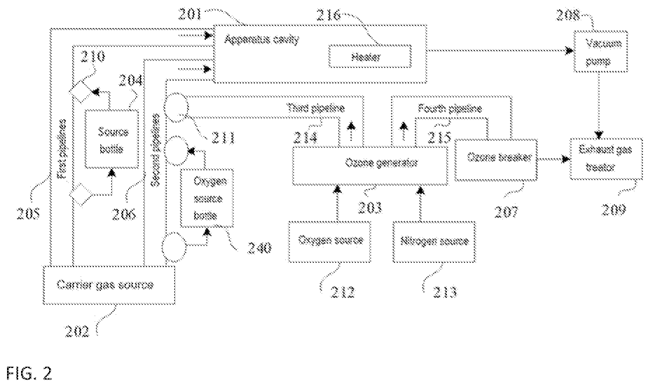

FIG. 2 illustrates a schematic structural diagram of a substrate treating apparatus according to an embodiment of the present application.

In view of problems in the prior art, as shown in FIG. 2, the present application provides a substrate treating apparatus, the apparatus is applied to performing a thermal atomic layer deposition on the substrate on a tubular PECVD equipment platform. The apparatus comprises: a carrier gas source 202, a plurality of first pipelines 205, a plurality of second pipelines 206, a source bottle 204, an ozone generator 203, a plurality of first fluid valves 210, a plurality of second fluid valves 211, and an apparatus cavity 201. The apparatus cavity 201 is applied to accommodating a substrate and serving as a reaction place thereof. Both the first pipelines 205 and the second pipelines 206 are applied to transmitting carrier gas to the apparatus cavity 201. The carrier gas source 202 is applied to supplying the carrier gas. The carrier gas is applied to purging the apparatus cavity 201. The ozone generator 203 is applied to supplying ozone. The source bottle 204 is applied to accommodating a chemical source. When the carrier gas is introduced into the source bottle 204, the carrier gas carries the chemical source before entering the apparatus cavity 201. The first fluid valves 210 are applied to controlling the source bottle 204 to communicate with the first pipelines 205. The second fluid valves 211 are applied to controlling the ozone generator 203 to communicate with the second pipelines 206.

In a plurality of other embodiments, the apparatus further comprises an oxygen source bottle 240, the oxygen source bottle 240 is applied to accommodating purified water. The oxygen source bottle 240 is communicated with the second pipelines 206 through the second fluid valves 211. When opening all the second fluid valves 211 connected with the oxygen source bottle 240, the carrier gas enters the oxygen source bottle 240, and the purified water in the oxygen source bottle 240 enters the apparatus cavity 201 through the second pipelines 206 before participating in a reaction.

In addition, both the oxygen source bottle 240 and the ozone generator 203 may be arranged on the second pipelines at a same time, while selecting an oxygen source by arranging a valve, water can be selected as an oxygen source, and ozone can also be selected as an oxygen source. That is, the oxygen source comprises at least two oxidants with different compositions, communicating with the second pipelines respectively, while at least one oxygen source is an ozone generator, and at least one oxygen source is an oxygen source bottle. Selecting by a valve may further select an oxygen source during each half reaction.

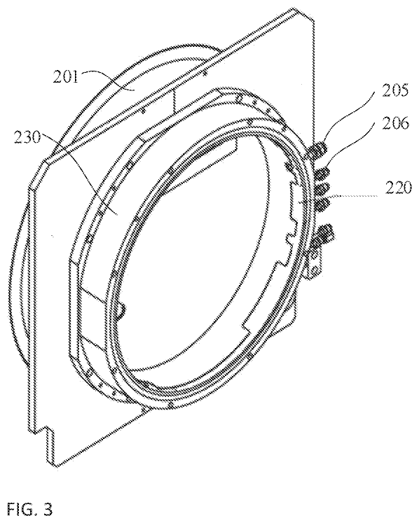

FIG. 3 illustrates a schematic structural diagram on a first apparatus cavity according to an embodiment of the present application.

As shown in FIG. 3, in a plurality of embodiments, the apparatus cavity 201 has a furnace mouth flange 230 connected. The furnace mouth flange 230 has a plurality of gas channels 220 arranged. Both the first pipelines 205 and the second pipelines 206 are connected with the furnace mouth flange 230. Both the first pipelines 205 and the second pipelines 206 are communicated with the apparatus cavity 201 through the plurality of gas channels 220.

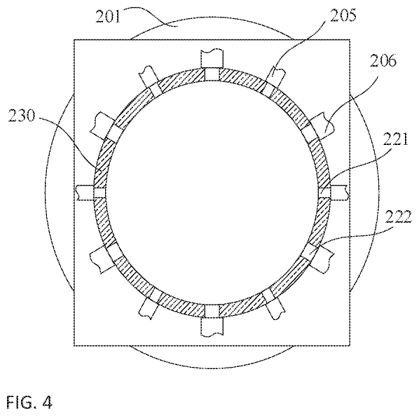

FIG. 4 illustrates a side view of a second apparatus cavity according to an embodiment of the present application.

As shown in FIG. 4, in a plurality of specific embodiments, the apparatus has a plurality of first gas channels 221 and a plurality of second gas channels 222 arranged, and both the plurality of first gas channels 221 and the plurality of second gas channels 222 are annularly distributed on one side of the apparatus cavity 201; the first gas channels 221 are connected with the first pipelines 205; and the second gas channels 222 are connected with the second pipelines 206. Such a design has avoided a premature mixing of the chemical source with the oxide in the first pipelines 205 or the second pipes 206 and the flange, as well as a plurality of associated safety problems. Annular distribution of the gas channels is beneficial for gas to enter the cavity uniformly, thereby avoiding a local gas concentration overhigh, and making a deposition reaction more uniform, thus a uniformity problem of aluminum oxide deposition in a PEALD process is solved. The oxide may be ozone, oxygen, or water. The chemical source may be one or more selected from an aluminum source, a gallium source, a titanium source, and a silicon source.

In a plurality of embodiments, the carrier gas source 202 is applied to supplying an inert gas or nitrogen, serving as a source carrier and a purging gas without participating in a deposition reaction. The first fluid valves 210 and the second fluid valves 211 are arranged as a plurality of pneumatic valves. The apparatus cavity 201 is arranged as a quartz tube. The apparatus cavity 201 has two gas inlets arranged, connecting respectively to the first pipelines 205 and the second pipelines 206. The source bottle 204 is located at one side of the first pipelines 205, having an inlet and an outlet, while both the inlet and the outlet of the source bottle 204 are communicated with the first pipelines 205 through two first fluid valves 210 respectively.

It should be noted that, in some embodiments, when the two first fluid valves 210 are both open, the carrier gas flows through the source bottle 204, and the carrier gas carries a chemical source before entering the apparatus cavity 201. The chemical source comprises at least one of the aluminum source, the gallium source, the titanium source, and the silicon source. The aluminum source comprises trimethylaluminum. When the two first fluid valves 210 are both closed, the carrier gas enters the apparatus cavity 201 directly through the first pipelines 205. The second fluid valves 211 are arranged at one side of the second pipelines 206. When the second fluid valves 211 are open, ozone generated by the ozone generator 203 flows to the apparatus cavity 201 through the second pipelines 206. The substrate treating apparatus provided by the present application is applicable to thermal atomic deposition of a plurality of oxides including aluminum oxide, gallium oxide, silicon oxide, titanium oxide and more, which is convenient for selecting a reaction precursor or a chemical source according to a requirement.

In a plurality of other embodiments, the carrier gas source 202 may further be applied to supplying a non-reactive gas. The first fluid valves 210 and the second fluid valves 211 are arranged as a solenoid valve or any other kind of valves. The apparatus cavity 201 may be any three-dimensional structure prepared by a plurality of other materials. The apparatus cavity 201 may have more than two gas inlets arranged. The source bottle 204 may be arranged at any position on the first pipelines 205.

In some embodiments, the carrier gas source 202 may have a conversion valve arranged, the conversion valve is applied to supplying the carrier gas to the first pipelines 205 or the second pipelines 206 selectively in a same flow. The conversion valve may directly change the carrier gas introduced into the first pipelines 205 to be introduced into the second pipelines 206 with a same flow, may also increase a flow of gas introduced into the second pipelines 206 at a same time of reducing that being introduced into the first pipelines 205 gradually, while the flow reduced in the first pipelines is as same as that increased in the second pipelines, making total flows of gas entering the cavity through the first pipelines 205 and through the second pipelines 206 are a same. Specifically, a three-way structure is adopted, wherein one inlet is the carrier gas source, one outlet has a control valve arranged before connecting with the first pipelines 205, another outlet has a control valve arranged before connecting with the second pipelines 206. Of course, the present application is not specifically limited, and any structure capable of implementing the functions stated above may be adopted.

In a plurality of embodiments, the apparatus further comprises an ozone destructor 207. The ozone destructor 207 is applied to processing any excess ozone generated by the ozone generator 203. The ozone destructor 207 has a plurality of beneficial effects including that keeping the ozone generator 203 in a power-on state, having a long-term air flow, thus keeping a flow and a concentration of the ozone being supplied in a stable state, while avoiding excess high-concentration ozone from causing any safety problems to the apparatus and an operator.

In a plurality of embodiments, the ozone generator 203 has a third pipeline 214 and a fourth pipeline 215 connected. The third pipeline 214 is connected with the second fluid valves 211, and the fourth pipeline 215 is connected with the ozone destructor 207. The second pipelines 206, the third pipeline 214, and the fourth pipeline 215 are all subjected to an anti-oxidation treatment.

In a plurality of embodiments, the ozone generator 203 has the third pipeline 214 connected, the third pipeline 214 is communicated with the second pipelines 206, and the third pipeline 214 has a flow meter (not shown in the figures) arranged inside, while the flow meter detects a flow of gas in the third pipeline. The second pipelines 206 have an exhaust pipeline arranged at a place close to the carrier gas source 202. An exhaust pipeline is arranged on the second pipelines 206 at a place close to the carrier gas source 202. By arranging the exhaust pipeline close to the carrier gas source 202, when being open, it is possible to avoid gas flowed into the second pipelines 206 from the third pipeline 214 from being exhausted. The exhaust pipeline comprises a flow controller, and the flow controller controls a flow in the exhaust pipeline to be as same as that of gas detected by the flow meter. When a flow of gas in the third pipeline is as same as that of exhausted gas, a flow of gas flowing into the cavity will not be changed.

When introducing a reaction gas from the source bottle 204, a flow difference before and after introducing the carrier gas into the source bottle 204 is relatively small, thus no additional exhaust structure will be required; of course, when the flow difference before and after introducing the carrier gas into the source bottle 204 is relatively large, the first pipelines 205 also has a corresponding structure arranged, and achieving a same flow by exhausting part of the gas. When adopting the source bottle 204 as an oxygen source to the second pipelines 206, if the flow difference before and after introducing the carrier gas into the source bottle 204 is over large, it is possible to adopt the gas exhaust pipeline of the second pipelines 206 to achieve an adjustment and control of the flow difference, before finally keeping the flow of the gas entering the cavity constant.

In addition, considering the carrier gas source 202 has the conversion valve arranged, the conversion valve is applied to selecting to supply the carrier gas in a same flow to the first pipelines 205 or the second pipelines 206, such that when carrying out an ALD reaction, a flow of the gas being introduced in a purging process between two half reactions is same, that lowers any variations of gas pressure and flow field between different processes, thereby keeping a constant gas pressure and gas flow during a whole ALD process, thus balancing a reaction process, and ensuring film forming quality and stable performance of a final cell.

In a plurality of specific embodiments, the anti-oxidation treatment comprises coating of aluminum oxide.

In a plurality of other specific embodiments, the anti-oxidation treatment comprises coating of silicon oxide.

In a plurality of other embodiments, the anti-oxidation treatment may comprise coating of any other anti-oxidation materials.

In a plurality of embodiments, the ozone generator 203 is connected with an oxygen source 212 and a nitrogen source 213. The nitrogen source 213 is applied to adjusting a concentration of the ozone generated by the ozone generator 203. The ozone concentration is set to [16, 20] wt %.

In a plurality of other embodiments, the ozone generator 203 may be connected with an oxygen source 212 and an inert gas source.

In a plurality of embodiments, the apparatus further comprises a vacuum pump 208. The vacuum pump 208 is applied to pumping out gas from the apparatus cavity 201.

In a plurality of other embodiments, the vacuum pump 208 may be arranged as a suction pump or other negative pressure equipment.

In a plurality of embodiments, the apparatus further comprises an exhaust gas treator 209. The exhaust gas treator 209 is applied to processing gas pumped out from the apparatus cavity 201. And the exhaust gas treator 209 is also applied to processing gas exhausted from the ozone destructor 207.

In a plurality of embodiments, the apparatus cavity 201 has a heater 216 arranged, and the heater 216 is applied to controlling a reaction temperature of the apparatus cavity 201.

In a plurality of other embodiments, the apparatus cavity 201 further has an auxiliary heat tube (not shown in the figure) arranged, the auxiliary heat tube (not shown in the figures) is applied to heating, such that the apparatus cavity 201 can be rapidly heated up to satisfy a requirement of a silicon nitride process. The auxiliary heat tube is arranged at an inner top of a furnace tube. After the aluminum oxide process is completed in the apparatus cavity 201, the auxiliary heat tube (not shown in the figures) is open to enable a faster temperature rise of the apparatus cavity 201, so as to shorten a temperature rise period as much as possible, and improve processing efficiency.

In a plurality of specific embodiments, an adjustable temperature range of the heater 216 is from room temperature to 530 degree Celsius. It should be noted that, the heater 216 is specifically arranged as a heating wire and a temperature detector; the heating wire is arranged outside the apparatus cavity 201 in an encircling mode, and heat generated by the heating wire is conducted to a substrate in a graphite boat through the apparatus cavity 201; the temperature detector has an inner coupling end, an outer coupling end, and an electrical end; the inner coupling end is arranged inside the apparatus cavity 201 and applied to sensing a temperature of the graphite boat; the outer coupling end is arranged outside the apparatus cavity 201 and applied to sensing a temperature of the heating wire; and the temperature of the heating wire is controlled by the electrical end, to keep the temperature of the apparatus cavity 201.

In a plurality of other embodiments, the heater 216 may be arranged in any forms, as long as it is possible to achieve an effect of enabling the substrate to reach a desired heating temperature and keeping a continuous temperature control.

In a plurality of embodiments, the apparatus cavity 201 has a plurality of graphite boats arranged inside. A number of the graphite boats is N, and N is a positive integer. The graphite boat is applied to loading the substrates. A number of the substrates loaded by the graphite boat is M, and M is a positive integer.

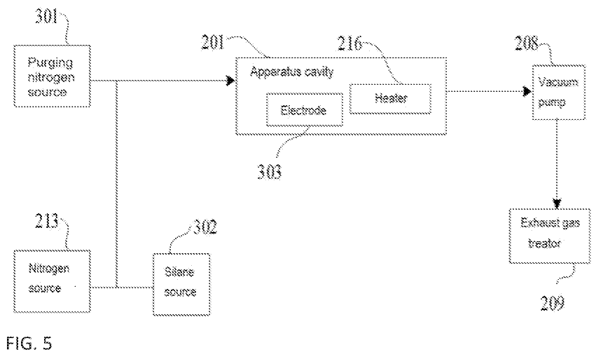

FIG. 5 illustrates a schematic structural diagram on another substrate treating apparatus according to an embodiment of the present application.

It is noted that, in a plurality of other embodiments, as shown in FIG. 5, the apparatus is further applied to carrying out a tubular plasma enhanced chemical vapor deposition process in the apparatus cavity 201. The apparatus cavity 201 has an electrode 303 arranged inside, and the apparatus cavity 201 is connected with a purging nitrogen source 301, a nitrogen source 213 and a silane source 302 through a single pipeline, while the nitrogen source 213 and the silane source 302 are transmitting to the apparatus cavity 201 in a mixed way in the single pipeline, achieving the tubular plasma enhanced chemical vapor deposition (PECVD) under an action of an electric field applied by electrifying the electrode 303. The purging nitrogen source 301 is applied to purging the apparatus cavity 201 when a reaction of the plasma enhanced chemical vapor deposition (PECVD) ends.

In a plurality of other embodiments, the apparatus is also capable of carrying out a silicon nitride process of PECVD, silane and ammonia enter the apparatus cavity 201 from the first pipelines 205, and nitrogen is introduced into the apparatus cavity 201 from the nitrogen source 301 through the second pipelines 206. The method avoids a problem that oxide remained in the apparatus cavity 201 after a previous aluminum oxide process reacts with the silane to generate a wrong product, and further avoids a problem that a process time is prolonged due to a long-time purging required by a single gas inlet.

According to another aspect of the present application, a substrate treating apparatus is provided, the apparatus integrates a first processing unit and a second processing unit; the first processing unit comprises: a carrier gas source, a plurality of first pipelines, a plurality of second pipelines, a source bottle, an oxygen source, a plurality of first fluid valves, a plurality of second fluid valves, and an apparatus cavity; wherein
the apparatus cavity is applied to accommodating a substrate and serving as a reaction place for the substrate;
both the first pipelines and the second pipelines are applied to transmitting carrier gas to the cavity;
the carrier gas source is applied to supplying the carrier gas;
the oxygen source is applied to supplying an oxidant;
the source bottle is applied to accommodating a chemical source; when the carrier gas is introduced into the source bottle, the carrier gas carries the chemical source before entering the apparatus cavity;
the first fluid valves are applied to controlling whether the chemical source flows through the first pipelines or not; and
the second fluid valves are applied to controlling whether the oxidant flows through the second pipelines or not;
wherein the first processing unit and the second processing unit share at least the carrier gas source and the apparatus cavity.

The present application, due to an arrangement of the pipelines, during a whole ALD process period, gas introduced into the cavity is injected into a vacuum environment through a door end of the cavity before flowing out through an opposite end, wherein a downstream of the gas outflow end has a pump with an inner part entering the cavity arranged, having a gas flow stable, thus, making a flow field of the process gas a stable laminar flow, and the process controlled, therefore being able to improve quality of the film layer, further improving quality of a product.

In a further solution, the first processing unit is a thermal ALD processing unit, and at least one path of gas in the thermal ALD processing unit is introduced into the apparatus cavity in a pulse mode; and the second processing unit is a PECVD processing unit, and gas in the PECVD processing unit is introduced into a same apparatus cavity in a non-pulse mode.

In a further solution, the PECVD processing unit and the thermal ALD processing unit share the carrier gas source and the apparatus cavity.

In a further solution, a vacuum process portion of the tubular equipment is a quartz tube with a hot wall, and a heater is a combination of heating wires or heating plates having not less than four temperature setting intervals.

In a further solution, the PECVD processing unit and the thermal ALD processing unit share the carrier gas source, the source bottle, and the apparatus cavity.

In a further solution, the oxygen source is a gaseous oxygen source or an active plasma oxide.

In a further solution, the plurality of reaction pipelines supply independently gas required by the process to the cavity.

It is noted that the further solutions stated above, as an optional feature set, may be arbitrarily combined, while all are within the scope of protection claimed by the present application.

In a first embodiment of the present application, the carrier gas source has a conversion valve arranged, the conversion valve is applied to selecting to supply a same flow of the carrier gas to the first pipelines or the second pipelines, that is, the carrier gas source continuously introduces a same flow of the carrier gas into a same tubular cavity through the first pipelines and the second pipelines alternately by the conversion valve, which makes the gas be outputted stably, therefore forming a uniform deposition layer when a first deposition layer, such as aluminum oxide, is deposited in a pulse mode.

In a second embodiment of the present application, the carrier gas source has a conversion valve arranged, the conversion valve is applied to selecting to supply a same flow of the carrier gas to the first pipelines or the second pipelines, that is, the carrier gas source continuously introduces a same flow of the carrier gas into a same tubular cavity through the first pipelines and the second pipelines alternately by the conversion valve. When the carrier gas is introduced from the carrier gas source into the tubular cavity through the second pipelines by the conversion valve, the gaseous oxygen source (such as an ozone generator) is communicated to the second pipelines through a third pipeline, and the third pipeline has a flow meter arranged inside, while the flow meter is applied to detecting a flow of the gas in the third pipeline; and the second pipelines have an exhaust pipeline arranged at a place close to the carrier gas source, the exhaust pipeline comprises a flow controller, the flow controller controls the exhaust pipeline to exhaust gas through the second pipelines, and a flow of the gas being exhausted is as same as the flow detected by the flow meter. The present embodiment can ensure that the flow introduced into the tubular cavity from the second pipeline is unchanged. In such a way, a same flow of the gas can be introduced into the same tubular cavity through the first pipelines and the second pipelines alternately, and the gas can be stably outputted, when a first half reaction step and a second half reaction step are carried out alternately in a later step. Therefore, when a first deposition layer, such as aluminum oxide, is deposited in such a pulse mode, a uniform deposition layer can be formed.

In a first embodiment of the present application, the first processing unit is a thermal atomic layer deposition processing unit (that is, a thermal ALD processing unit), and at least one path of gas in the thermal ALD processing unit is introduced into the apparatus cavity in a pulse mode, so as to form a first deposition layer on the substrate. The second processing unit is a plasma enhanced chemical vapor deposition unit (that is, a PECVD processing unit), gas of the PECVD processing unit is introduced into a same apparatus cavity in a non-pulse mode, so as to further form a second deposition layer different from the first deposition layer on the substrate.

In a second embodiment of the present application, the substrate treating apparatus has a tubular cavity. The first processing unit is a thermal atomic layer deposition processing unit (that is, a thermal ALD processing unit), and at least one path of gas in the thermal ALD processing unit is introduced into the tubular cavity in a pulse mode, so as to form a first deposition layer on the substrate. The second processing unit is a plasma enhanced chemical vapor deposition unit (that is, a PECVD processing unit), gas of the PECVD processing unit is introduced into a same tubular cavity in a non-pulse mode, so as to further form a second deposition layer different from the first deposition layer on the substrate.

It shall be noted herein that the thermal ALD processing adopted in the present application is different from PEALD processing. PEALD processing is complex due to the PEALD processing requiring control of a plasma reaction, having a control process complex.

Wherein, the oxygen source is preferably a gaseous oxygen source.

Due to both the first deposition layer and the second deposition layer being formed in a same apparatus cavity, while the second deposition layer is formed by the plasma enhanced chemical vapor deposition unit in the non-pulse mode, and the first deposition layer is formed by the thermal atomic layer deposition processing unit in the pulse mode, the first deposition layer often cannot be deposited on the substrate uniformly, which affects molding quality of a chip substrate seriously, often leads to an unqualified product.

In order to enable the first deposition layer formed by the thermal atomic layer deposition processing unit to the tubular cavity in the pulse mode to be uniformly deposited on the substrate, the present application provides a plurality of embodiments as follows:

In one embodiment of the present application, the carrier gas source has a conversion valve arranged, and the conversion valve is applied to selecting to supply the carrier gas in a same flow to the first pipelines or the second pipelines. The present embodiment can ensure that a flow of the gas introduced into the apparatus cavity from the second pipelines is as same as that introduced into the tubular cavity from the first pipelines, thus a flow of gas exhausted from the second pipelines is as same as a flow of the gas in the first pipelines, in such a way, the gas can be outputted stably. Therefore, when a first deposition layer, such as aluminum oxide, is deposited in a pulse mode, a deposition layer will be formed uniformly.

Further, the carrier gas source has the conversion valve arranged, and the conversion valve is applied to selecting to supply the carrier gas in a same flow to the first pipelines or the second pipelines, that is, the carrier gas source introduces continuously a same flow of the carrier gas into a same tubular cavity alternately through the first pipelines and the second pipelines by the conversion valve. When the gaseous oxygen source (such as an ozone generator) is communicated to the second pipelines through a third pipeline, a flow meter is arranged in the third pipeline, and the flow meter is applied to detecting a flow of the gas in the third pipeline; and the second pipelines have an exhaust pipeline arranged at a place close to the carrier gas source, the exhaust pipeline comprises a flow controller, the flow controller controls the exhaust pipeline to exhaust gas from the second pipelines, making a flow of the gas exhausted in the second pipelines is as same as a flow of the gas detected by the flow meter in the third pipeline. The present embodiment can ensure that the flow introduced into the tubular cavity from the second pipelines is unchanged. In such a way, it also achieves that the same flow of gas can be introduced into the same tubular cavity alternately through the first pipelines and the second pipelines, which makes the gas be outputted stably when a first half reaction step and a second half reaction step are carried out alternately. Therefore a deposition layer can be formed uniformly, when a first deposition layer, such as aluminum oxide, is deposited in a pulse mode.

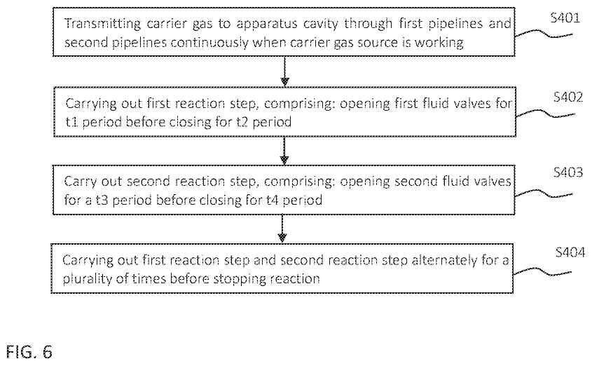

FIG. 6 illustrates a flow diagram on a substrate treating method according to an embodiment of the present application.

Base on the substrate treating apparatus stated above, the present application provides a substrate treating method, applied to the apparatus stated in anyone above. As shown in FIG. 6, the method comprises following steps:

S401. Transmitting the carrier gas to the apparatus cavity 201 through the first pipelines 205 and the second pipelines 206 continuously when the carrier gas source 202 is working.

In a plurality of embodiments, when the substrate enters the apparatus cavity 201, the heater 216 heats up the cavity before heating up the substrate through thermal conduction. The carrier gas source 202 fills the apparatus cavity 201 with the carrier gas to carry out a pressure maintaining test. The vacuum pump 208 pumps out the gas in the apparatus cavity 201. By the conversion valve, the carrier gas source introduces a same flow of carrier gas into the cavity continuously through the first pipelines or the second pipelines. In this way, the present embodiment is able to ensure that a flow of the gas introduced into the apparatus cavity 201 from the second pipelines 206 is as same as that introduced into the apparatus cavity 201 from the first pipelines 205.

In a plurality of specific embodiments, a heating period for the heater 216 to heat up the substrate is 5 to 10 minutes, the heating period depending on a state of the graphite boats and a state of the cavity being heated up. The pressure maintaining test comprises that the apparatus cavity 201 has a pressure change no more than 3 Pa in 15 s.

S402. Carrying out a first reaction step, comprising: opening the first fluid valves 210 for a t1 period before closing for a t2 period. When the first fluid valves 210 are open, the carrier gas carries the chemical source to enter the apparatus cavity 201 through the first pipelines 205; and when the first fluid valves 210 are closed, the carrier gas source 202 purges the carrier gas into the apparatus cavity 201.

S403. Carry out a second reaction step, comprising: opening the second fluid valves 211 for a t3 period before closing for a t4 period. When the second fluid valves 211 are open, the ozone generator 203 transmits ozone to the apparatus cavity 201 through the second pipelines 206; when the second fluid valves 211 are closed, the carrier gas source 202 purges the carrier gas to the apparatus cavity 201.

S404. Carrying out the first reaction step and the second reaction step alternately for a plurality of times before stopping a reaction.

It is noted that, by carrying out the first reaction step and the second reaction step alternately, the thermal atomic layer deposition is achieved, and the thin film conformality on the substrate surface texturing morphology is improved, while passivated surface damages are avoided, thereby being beneficial for achieving a best passivation effect.

In a plurality of embodiments, after the reaction is stopped, the pipelines and the cavity are purged with the carrier gas, and the vacuum pump 208 stops pumping out gas. After the vacuum is broken, the graphite boats are moved out of the apparatus cavity 201.

In a plurality of embodiments, the ozone generator 203 is kept being on, and excess ozone generated by the ozone generator 203 is processed by the ozone destructor 207. When supplying gas to the second pipelines through the third pipeline, by the exhaust pipeline arranged on the second pipeline at a place close to the carrier gas source, the carrier gas in the second pipelines 206 is exhausted out, while the flow of the gas exhausted is as same as the flow of the gas in the third pipeline.

When the second fluid valves 211 are open, ozone generated by the ozone generator 203 enters the second pipelines 206 through the third pipeline 214, and finally enters the apparatus cavity 201. When the second fluid valves 211 are closed, ozone generated by the ozone generator 203 enters the ozone destructor 207 through the fourth pipeline 215. The ozone destructor 207 destroys most of the ozone, and a small part of the ozone enters the exhaust gas treator 209 for a complete reaction, so as to prevent the ozone from polluting the environment.

In a plurality of embodiments, the gas pumped out from the apparatus cavity 201 by the vacuum pump 208 is introduced into the exhaust gas treator 209. The gas exhausted from the ozone destructor 207 is introduced into the exhaust gas treator 209.

In a plurality of embodiments, the chemical source comprises trimethylaluminum. A surface of the substrate has a layer of hydroxyl arranged, satisfying a following chemical reaction formula:

nsurf-OH+Al(CH₃)₃→surf-O—Al(CH₃)₃₋ₙ+nCH₄

wherein, n is 1 or 2.

In a plurality of embodiments, the first reaction step satisfies a following chemical reaction formula:

nsurf-AlOH+Al(CH₃)₃→surf-(nAl)—O—Al(CH₃)₃₋ₙ+nCH₄

wherein, n is 1 or 2. The second reaction step satisfies the following chemical reaction formula:

(3-n)surf-AlCH₃+(3-n)O₃→(3-n)surf-AlCH₂OH+(3-n)O₂

wherein, n is 1 or 2. A product of the second reaction step satisfies a following chemical reaction formula:

2surf-AlCH₂OH→2surf-AlOH+C₂H₄.

It shall be noted that, the ozone in a plurality of reactants of the second reaction step may be partially or completely replaced by purified water. A product obtained at this time still comprises surf-AloOH, which does not affect the first reaction step and the second reaction step to be performed alternately.

In a plurality of embodiments, after the substrate completes the thermal ALD process in the apparatus cavity 201, the substrate continues to subject the PECVD process in the apparatus cavity 201.

It shall be noted that the PECVD processing unit and the thermal ALD processing unit share the carrier gas source and the source bottle.

In a plurality of specific embodiments, a plurality of parameters adopted by the substrate treating method are shown as Table 1, and the temperatures of the apparatus cavity 201 at moments T1-T6 are all set as 200 degrees Celsius. The carrier gas source 202 adopts argon with a flow value of 2500 standard milliliters per minute. A flow value of the ozone is set as 3000 standard milliliters per minute and a concentration as 18.5 wt %. The chemical source adopts trimethylaluminum (TMA). The first fluid valves 210 are open for 5 seconds before being closed for 7 seconds. The second fluid valves 211 are open for 7 seconds before being closed for 8 seconds. An operation of 27 seconds in total stated above is one cycle.

TABLE 1

| Temperature (° C.) | | | | | | Ar | O₃ | O₃ | TMA | | O₃ | |
|---|---|---|---|---|---|---|---|---|---|---|---|---|
| T1 | T2 | T3 | T4 | T5 | T6 | (sccm) | (sccm) | ratio | on(s) | off (s) | on (s) | off (s) |

| | | | | | | | |
|---|---|---|---|---|---|---|---|
| 200 | 2500 | 3000 | 18.50 wt % | 5 | 7 | 7 | 8 |

In a plurality of specific embodiments, the graphite boats are arranged as eight: A-H. Each graphite boat has 56 substrates loaded, and each substrate has a unique location in the graphite boat. After the cycle has been carried out for 500 times, a thickness test is carried out onto a substrate testing point by an elliptical polarizer.

In a plurality of other embodiments, the temperature may be set as any temperature between [130, 250] degrees Celsius, the carrier gas source 202 may adopt an inert gas or other non-reactive gas, and a flow value may be any positive number. The flow value and the concentration of the ozone can be set as any positive number. An open period and a close period of the first fluid valves 210 and the second fluid valves 211 can be set as any positive number. A number of the graphite boats can be set as any positive integer. Times of the cycle being carried out may be any positive integer number.

According to another aspect of the present application, a substrate treating method is provided. By the treating method, it is possible to keep the flow of the gas in the cavity unchanged during a process of thermal ALD, thereby achieving uniformity of a thin film processed by thermal ALD. That is, the substrate treating method in the present embodiment adopts the substrate treating apparatus in the present application to carry out thermal atomic layer deposition processing (that is, thermal ALD processing) and plasma enhanced chemical vapor deposition processing (that is, PECVD processing) onto the substrate in a same tubular cavity. The thermal ALD processing comprises:
transmitting the carrier gas to the apparatus cavity 201 through the first pipelines and the second pipelines continuously when the carrier gas source is working;
carrying out a first half reaction step, comprising: opening the first fluid valves for a t1 period before closing for a t2 period;
the carrier gas carrying the chemical source before entering the apparatus cavity 201 through the first pipelines, when the first fluid valves are open;
the carrier gas source purging the carrier gas into the apparatus cavity 201, when the first fluid valves are closed;
carrying out a second half reaction step, comprising: opening the second fluid valves for a t3 period before closing for a t4 period;
the ozone generator transmitting ozone to the apparatus cavity 201 through the second pipeline when the second fluid valves are open;
the carrier gas source purging the carrier gas to the apparatus cavity 201 when the second fluid valves are closed; and
carrying out the first reaction step and the second reaction step alternately for a plurality of times before stopping a reaction.

Wherein after the substrate completes the thermal ALD process in the tubular cavity, the substrate continues to subject the PECVD process in the same tubular cavity.

Thus, it is possible to form the first deposition layer in the tubular cavity in a pulse mode based on the thermal ALD processing, including aluminum oxide, silicon oxide, gallium oxide, titanium oxide or other oxides; followed by forming the second deposition layer different from the first deposition layer in the same tubular cavity in a non-pulse mode by the PECVD processing, such as silicon nitride.

Since the first deposition lay and the second deposition layer are formed in the same tubular cavity, and the second deposition layer is formed by the PECVD unit in the non-pulse mode in the tubular cavity, while the first deposition layer is formed by the thermal ALD processing unit in a pulse mode in the same tubular cavity, thus the first deposition layer often cannot be deposited on the substrate uniformly, which affects the molding quality of a chip substrate seriously, and often causes an unqualified product.

In order to enable the first deposition layer formed in the tubular cavity by the thermal atomic layer deposition processing unit in the pulse mode to be deposited uniformly on the substrate, the present application provides a plurality of following embodiments:

In a first embodiment of the present application, when the substrate enters the tubular cavity, the heater heats up the substrate; the carrier gas source fills the carrier gas into the tubular cavity before carrying out a pressure maintaining test, while the vacuum pump pumps out gas in the tubular cavity. Wherein the carrier gas source introduces a same flow of the carrier gas into the tubular cavity alternately through the first pipelines and the second pipelines by the conversion valve. The present embodiment can ensure that the flow of the carrier gas introduced into the apparatus cavity 201 from the second pipelines 206 is as same as that introduced into the apparatus cavity 201 from the first pipelines 205, making the flow of the carrier gas exhausted in the second pipelines is as same as the flow of the carrier gas in the first pipeline. Thus by introducing the same flow of the carrier gas into the tubular cavity alternately through the first pipelines and the second pipelines, the carrier gas can be stably outputted when the first half reaction step and the second half reaction step are carried out alternately. Therefore, it is possible to enable the first deposition layer, such as aluminum oxide, when being deposited in a pulse mode, to form a uniform deposition layer.

In a second embodiment of the present application, when the substrate enters the tubular cavity, the heater heats up the substrate; the carrier gas source fills the carrier gas into the tubular cavity before carrying out a pressure maintaining test, while the vacuum pump pumps out gas in the tubular cavity. Wherein the carrier gas source introduces continuously a same flow of carrier gas into the same tubular cavity alternately through the first pipelines and the second pipelines by the conversion valve. When the carrier gas source introduces the carrier gas into the tubular cavity through the second pipelines by the conversion valve, the ozone generator is communicated to the third pipeline and kept in an on state, the ozone generator introduces the ozone of a first flow into the second pipelines through the third pipeline. The third pipeline has a flow meter arranged in, and the flow meter is applied to detecting a flow of the ozone in the third pipeline; meanwhile, the second pipelines has an exhaust pipeline arranged at a place close to the carrier gas source, a flow controller on the exhaust pipeline is applied to controlling the exhaust pipeline to exhaust gas from the second pipelines, making a flow of the exhausted gas from the second pipelines as same as that of the ozone detected by the flow meter in the third pipeline, so as to ensure a sum of the flow of the carrier gas obtained from the second pipelines and a flow of the ozone obtained from the second pipelines through the third pipeline to be as same as the flow of the carrier gas obtained from the first pipelines. In such a way, it is also possible to achieve a steady output of the gas when the first half reaction step and the second half reaction step are alternately carried out. Therefore, by making the gas be able to be output steadily, it is possible to make a first deposition layer, such as aluminum oxide, form a uniform deposition layer, when being deposited in such a pulse mode.

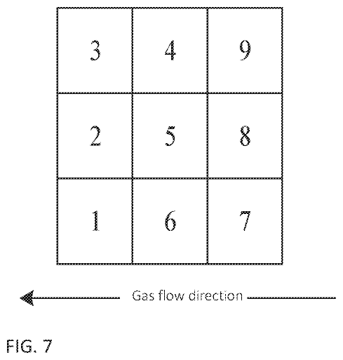

FIG. 7 illustrates a schematic diagram on a region division to the substrate according to the present application.

Further, a thickness test is carried out on the substrate having been treated in the embodiment stated above. As shown in FIG. 7, a method to select testing points of the substrate is: dividing the substrate into nine regions, and taking a center point of each region as a testing point. In an embodiment, the substrate has a side length of 210 mm, a testing result is shown in Table 2: by counting a thickness of 9 testing points in the same substrate (Thickness of SE testing point), it can obtain a mean value (Mean), a within wafer (WIW) uniformity and a thickness growth per cycle (GPC) easily. While a wafer-to-wafer (WTW) uniformity can be obtained by counting the thicknesses of testing points in different substrates.

TABLE 2

| | Thickness of SE testing point (nm) | | | | | | | | | Mean | | | GPC |
|---|---|---|---|---|---|---|---|---|---|---|---|---|---|
| Location | 1 | 2 | 3 | 4 | 5 | 6 | 7 | 8 | 9 | (nm) | WIW | WTW | (nm/cycle) |
| A-3-1 | 52.88 | 52.18 | 53.41 | 53 | 52.75 | 52.81 | 54.24 | 53.77 | 53.88 | 53.21 | 1.94% | 3.01% | 0.106427 |
| A-14-1 | 53.73 | 53.1 | 53.85 | 54.45 | 53.71 | 53.62 | 55.45 | 55.9 | 55.07 | 54.32 | 2.58% | | 0.10864 |
| A-26-1 | 52.59 | 52.32 | 53 | 52.57 | 52.64 | 52.51 | 53.41 | 53.41 | 52.97 | 52.82 | 1.03% | | 0.105649 |
| B-3-1 | 52.55 | 51.53 | 53.01 | 52.9 | 51.82 | 52.27 | 52.73 | 51.39 | 53.04 | 52.36 | 1.58% | | 0.10472 |
| B-14-1 | 53.86 | 52.01 | 53.32 | 53.15 | 52.33 | 53.4 | 53.38 | 52.44 | 53.43 | 53.04 | 1.74% | | 0.106071 |
| B-26-1 | 52.03 | 51.7 | 53.49 | 52.69 | 51.62 | 52.3 | 51.76 | 52.08 | 52.68 | 52.26 | 1.79e | | 0.104522 |
| C-3-1 | 52.66 | 51.69 | 52.92 | 52.53 | 51.4 | 52.05 | 52.42 | 51.41 | 52.9 | 52.22 | 1.46% | | 0.104447 |
| C-14-1 | 53.34 | 51.97 | 53.66 | 52.84 | 51.88 | 53.1 | 53.18 | 51.81 | 52.77 | 52.73 | 1.75% | | 0.105456 |
| C-26-1 | 52.16 | 51.68 | 52.91 | 52.35 | 51.45 | 51.95 | 52.39 | 51.98 | 52.6 | 52.16 | 1.40% | | 0.104327 |
| D-3-1 | 52.13 | 52.09 | 52.88 | 52.53 | 51.52 | 52.42 | 51.86 | 51.42 | 52.62 | 52.16 | 1.40% | | 0.104327 |
| D-14-1 | 53.98 | 52.32 | 52.47 | 52.3 | 52.08 | 53.63 | 53.45 | 52.07 | 52.68 | 52.78 | 1.81% | | 0.105553 |
| D-26-1 | 52.44 | 51.47 | 52.53 | 52.17 | 51.03 | 51.71 | 51.82 | 51.32 | 51.94 | 51.83 | 1.45% | | 0.103651 |
| E-3-1 | 52.44 | 51.21 | 52.61 | 51.98 | 51.42 | 51.79 | 52.22 | 52.24 | 51.79 | 51.97 | 1.35% | | 0.103933 |
| E-14-1 | 54.57 | 53.63 | 52.94 | 52.7 | 53.1 | 54.28 | 54.79 | 54.39 | 52.82 | 53.69 | 1.95% | | 0.107382 |
| E-26-1 | 52.43 | 50.95 | 52.68 | 51.92 | 50.96 | 51.65 | 52.12 | 51.51 | 52.18 | 51.82 | 1.67% | | 0.103644 |
| F-3-1 | 52.46 | 51.07 | 52 | 51.58 | 50.7 | 51.77 | 51.57 | 50.64 | 51.68 | 51.50 | 1.77% | | 0.102993 |
| F-14-1 | 54.34 | 53.08 | 51.95 | 51.77 | 52.65 | 53.46 | 53.96 | 53.18 | 51.62 | 52.89 | 2.57% | | 0.10578 |
| F-26-1 | 52.63 | 51.14 | 52.05 | 51.22 | 50.43 | 51.73 | 51.99 | 50.23 | 51.73 | 51.46 | 2.33% | | 0.102922 |
| G-3-1 | 52.18 | 51.04 | 51.43 | 51.02 | 50.39 | 51.96 | 51.72 | 50.25 | 51.4 | 51.27 | 1.88% | | 0.102531 |
| G-14-1 | 54.4 | 53.22 | 51.74 | 51.24 | 52.4 | 54.13 | 54.06 | 52.61 | 51.32 | 52.79 | 2.99% | | 0.105582 |
| G-26-1 | 52.07 | 50.85 | 51.1 | 50.96 | 49.92 | 51.94 | 52.27 | 50.32 | 51.12 | 51.17 | 2.30% | | 0.102344 |
| H-3-1 | 51.99 | 50.85 | 50.94 | 50.78 | 50.71 | 52.32 | 52.27 | 50.43 | 51.25 | 51.28 | 1.84% | | 0.102564 |
| H-14-1 | 54.17 | 2.87 | 52.01 | 51.47 | 53.2 | 54.22 | 54.2 | 53.1 | 51.32 | 52.95 | 2.749 | | 0.105902 |
| H-26-1 | 52.07 | 50.75 | 51.1S | 51.12 | 50.31 | 51.79 | 52.37 | 50.63 | 50.84 | 51.23 | 2.01% | | 0.102451 |

It can be easily seen from the Table 2 that, after 500 cycles, the substrate can achieve a WIW uniformity in a range of 0 to 3% and a WTW uniformity in a range of 0 to 3.01%.

In a plurality of other embodiments, the substrate is divided into X regions, and X is a positive integer. A diameter of the substrate is any size smaller than a size of the graphite boat.

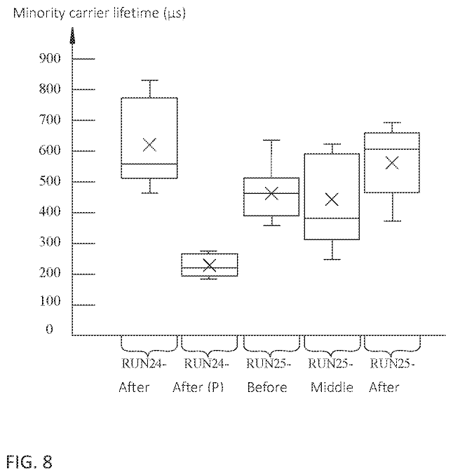

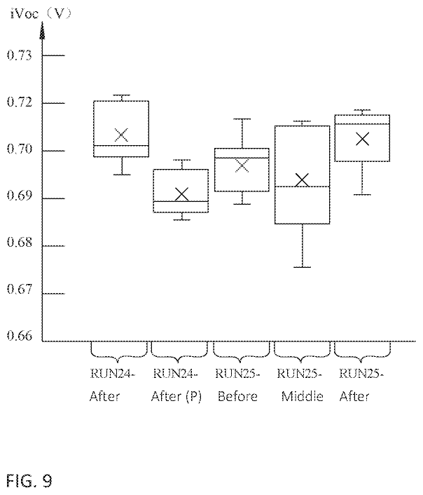

FIG. 8 illustrates a box diagram on a minority carrier lifetime of a substrate according to an embodiment of the present application; and FIG. 9 illustrates a box diagram on an implied open circuit voltage of a substrate according to an embodiment of the present application.

In a plurality of other specific embodiments, the substrate is coated with 15 nm aluminum oxide on both sides by the substrate treating method, before being vacuum annealed at 450° C. for 30 minutes. A minority carrier lifetime of the substrate after the process is debugged and stabilized is tested by sintoninstrument WCT-120 or other measurement equipment. As an embodiment, a 24th process and a 25th process in a process development process are selected as experimental samples in the present embodiment, and testing results are shown in FIG. 8. Wherein a mean of the minority carrier lifetimes of an n-type substrate is higher than 450 μs, while a mean of minority carrier lifetimes of a p-type substrate is higher than 200 μs. Results of a test on an implied open circuit voltage (iVOC) of the substrate in the 24th and the 25th process experiments are shown in FIG. 9. Wherein a mean of iVOC at each time node is higher than 0.69 V, that is, both a previous passivation level and a subsequent passivation level are at a relatively high level. It is noted that, the minority carrier lifetime and the iVOC are in a variation trend of positive correlation.

In summary, for a plurality of applications of a TOPCon cell, the embodiment of the present application is able to carry out a uniform aluminum oxide deposition on a large-size substrate, especially having an excellent conformality and passivation effect on a texturing surface of an n-type substrate, ensuring an efficient utilization of light energy by the TOPCon cell. In the embodiment of the present application, since the PECVD equipment platform is reused when the substrate is subjected to thermal atomic deposition, a process of both aluminum oxide and silicon nitride in a same boat is achieved, thereby production cost is reduced to a certain extent.

While the embodiments of the present application have been described in detail above, it will be apparent to those skilled in the art that various modifications and variations can be made to the embodiments. It should be understood, however, that such modifications and variations are within the scope and spirit of the present application as set forth in the claims. Moreover, the present application described herein is capable of other embodiments and of being practiced or of being carried out in various ways.

1. A substrate treating apparatus, wherein integrating a thermal ALD processing unit and a PECVD processing unit; the thermal ALD processing unit comprising: a carrier gas source, a plurality of first pipelines, a plurality of second pipelines, a source bottle, an oxygen source, a plurality of first fluid valves, a plurality of second fluid valves and an apparatus cavity;
the apparatus cavity is applied to accommodating a substrate and serving as a reaction place for the substrate;
both the first pipelines and the second pipelines are applied to transmitting carrier gas to the apparatus cavity;
the carrier gas source is applied to supplying the carrier gas; the oxygen source is applied to supplying an oxidant;
the source bottle is applied to accommodating a chemical source; when the carrier gas is introduced into the source bottle, the carrier gas carries the chemical source before entering the apparatus cavity;
the first fluid valves are applied to controlling whether the chemical source flows through the first pipelines or not;
the second fluid valves are applied to controlling whether the oxidant flows through the second pipelines or not.

2. The apparatus according to claim 1, wherein the oxygen source comprises at least two oxidants of different compositions, communicated with the second pipelines respectively.

3. The apparatus according to claim 2, wherein at least one oxygen source is an ozone generator, and at least one oxygen source is an oxygen source bottle.

4. The apparatus according to claim 3, wherein the ozone generator has a third pipeline connected, the third pipeline is communicated with the second pipelines, the third pipeline has a flow meter arranged inside, and the flow meter is applied to detecting a flow of the gas in the third pipeline; and
the second pipelines have an exhaust pipeline arranged at a place close to the carrier gas source, the exhaust pipeline comprises a flow controller, the flow controller controls the exhaust pipeline to exhaust gas through the second pipelines, and a flow of the gas being exhausted is as same as the flow detected by the flow meter.

5. The apparatus according to claim 1, wherein the source bottle and the first pipeline are arranged in parallel; and
the carrier gas flows through at least one of the source bottle and the first pipelines.

6. The apparatus according to claim 1, wherein the source bottle has an adjustment portion arranged for adjusting a flow of the gas entering the source bottle;
when the carrier gas flows simultaneously through the source bottle and the first pipelines, the adjustment portion is applied to adjusting a ratio of a flow of the gas distributed to the source bottle.

7. The apparatus according to claim 1, wherein the carrier gas source has a conversion valve arranged, and the conversion valve is applied to selecting to supply the carrier gas in a same flow to the first pipelines or the second pipelines.

8. The apparatus according to claim 1, wherein the apparatus cavity has a furnace mouth flange arranged; both the first pipelines and the second pipelines are connected with the furnace mouth flange; and
the furnace mouth flange has a plurality of gas channels arranged, each gas channel is applied to communicating the apparatus cavity with the first pipelines or the second pipelines respectively.

9. The apparatus according to claim 3, wherein further comprising an ozone destructor;
the ozone destructor is applied to processing any excess ozone generated by the ozone generator;
the ozone generator has the third pipeline and a fourth pipeline connected;
the third pipeline is connected with the second fluid valves, and the fourth pipeline is connected with the ozone destructor.

10. The apparatus according to claim 1, wherein each pipeline is subjected to an anti-oxidation treatment.

11. The apparatus according to claim 10, wherein
the anti-oxidation treatment comprises coating with aluminum oxide.

12. The apparatus according to claim 3, wherein
the ozone generator is connected with an oxygen source and a nitrogen source;
the nitrogen source is applied to controlling a concentration of the ozone generated by the ozone generator; and a concentration of the ozone is set as [16, 20] wt %.

13. The apparatus according to claim 1, wherein the apparatus cavity comprises a heater, applied to controlling a reaction temperature of the apparatus cavity.

14. The apparatus according to claim 13, wherein the apparatus cavity further having an auxiliary heat tube arranged, and the auxiliary heat tube is applied to heating, enabling a fast temperature rise of the apparatus cavity.

15. The apparatus according to claim 1, wherein the PECVD processing unit and the thermal ALD processing unit sharing the carrier gas source and the source bottle.

16. A substrate treating method, adopting the apparatus according to claim 1, carrying out thermal ALD and PECVD processing on a substrate in a same cavity, wherein the thermal ALD processing comprising:
transmitting the carrier gas to the apparatus cavity through the first pipelines and the second pipelines continuously when the carrier gas source is working;
carrying out a first reaction step, comprising: opening the first fluid valves for a t1 period before closing for a t2 period;
the carrier gas carrying the chemical source before entering the apparatus cavity through the first pipelines, when the first fluid valves are open;
and the carrier gas source purging the carrier gas into the apparatus cavity when the first fluid valves are closed;
carrying out a second reaction step, comprising: opening the second fluid valves for a t3 period before closing for a t4 period;
the ozone generator transmitting ozone to the apparatus cavity through the second pipelines when the second fluid valves are open;
the carrier gas source purging the carrier gas to the apparatus cavity when the second fluid valves are closed; and
carrying out the first reaction step and the second reaction step alternately for a plurality of times before stopping a reaction.

17. The method according to claim 16, wherein
when the substrate enters the apparatus cavity, the heater heats up the substrate; and
the carrier gas source fills the apparatus cavity with the carrier gas, and the carrier gas source introduces continuously a same flow of the carrier gas into the cavity through the first pipelines or the second pipelines by the conversion valve.

18. The method according to claim 16, wherein the ozone generator is kept in an on state, and excess ozone generated by the ozone generator is treated by the ozone destructor.

19. The method according to claim 16, wherein the ozone generator is kept in the on state, when supplying gas to the second pipelines through the third pipeline, the exhaust pipeline arranged on the second pipeline and close to the carrier gas source exhausts the carrier gas in the second pipelines out, and a flow of the gas exhausted is as same as a flow of the gas in the third pipeline.

20. The method according to claim 18, wherein gas pumped out from the apparatus cavity by the vacuum pump is introduced into the exhaust gas treator; and
gas exhausted from the ozone destructor is introduced into the exhaust gas treator.

21. The method according to claim 16, wherein the substrate continuing to perform the PECVD process in the apparatus cavity, after the substrate completing the thermal ALD process in the apparatus cavity.
